(19) United States
(12) Patent Application Publication
(10) Pub. No.: US 2006/0087000 A1
(43) Pub. Date: Apr. 27, 2006

(54) Semiconductor device and manufacturing method thereof

(75) Inventor: Yasutoshi Okuno, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/097,142

(22) Filed: Apr. 4, 2005

(30) Foreign Application Priority Data
Oct. 22, 2004 (JP) 2004-308695

(51) Int. Cl. H01L 29/00

(52) U.S. Cl. 257/506

(57) ABSTRACT

A semiconductor device has a semiconductor layer of silicon which has a plurality of element formation regions, and a trench isolation region for isolating the plurality of element formation regions from each other. The trench isolation region is formed by filling a trench formed in an upper part of the semiconductor layer with an insulating metal nitride. A thermal expansion coefficient of the insulating metal nitride is closer to that of silicon than a thermal expansion coefficient of silicon oxide is to that of silicon.

### CROSS REFERENCE TO RELATED APPLICATIONS

This application claims priority under 35 U.S.C. §119 on Patent Application No. 2004-308695 filed in Japan on Oct. 22, 2004, the entire contents of which are hereby incorporated by reference.

### BACKGROUND OF THE INVENTION

The present invention generally relates to a semiconductor device and a manufacturing method thereof. More particularly, the present invention relates to a semiconductor device having trench isolation for isolating a plurality of elements from each other, and a manufacturing method thereof.

For higher integration of elements, shallow trench isolation (STI) technology has been mainly used as an element isolation technology for elements of 0.25 μm or less design rule. In this technology, shallow trench isolation (STI) is formed by forming grooves (trenches) of about 0.2 μm to about 0.3 μm deep in a main surface of a semiconductor substrate and filling the trenches with an insulating material. With recent improvement in miniaturization of elements, however, stress resulting from STI has produced new problems in a production process such as variation in characteristics of elements, generation of crystal defects in active regions, and the like. Such problems reduce reliability of elements.

Stress resulting from STI is generated by the difference in a thermal expansion coefficient between silicon (Si) forming a substrate and silicon oxide (SiO₂) filling STI trenches. Generation of such stress cannot be avoided as long as silicon oxide is used as an insulating material for filling the trenches.

In order to reduce stress resulting from STI, it has been suggested that an insulating material whose thermal expansion coefficient is close to that of silicon is used as an STI filler (for example, U.S. Pat. No. 6,653,200). In this United States patent, a mixture of aluminum oxide and silicon oxide (Al₂O₃—SiO₂) or a mixture of zirconia and silicon oxide (ZrO₂—SiO₂) is mainly used as an insulating trench filler in order to reduce stress resulting from STI. In this case, the composition of each mixed oxide is precisely controlled to obtain a trench filler having a thermal expansion coefficient close to that of silicon.

### SUMMARY OF THE INVENTION

Recent improvement in miniaturization of elements has increased not only stress resulting from STI but power consumption per unit area such as an off-state current and a gate current of transistors. As well known in the art, increased power consumption per unit area raises the temperature of elements, resulting in reduced reliability of the elements. Therefore, cooling of element regions must be considered as well.

In order to obtain reliable elements, it is necessary both to reduce stress resulting from STI and to cool element regions. In order to cool element regions efficiently, heat within elements must be released to the outside by using a material having high thermal conductivity.

Thermal conductivity is a physical property value specific to each material. Silicon (Si) has thermal conductivity of 148 W/m·K and silicon oxide (SiO₂) which forms conventional STI has thermal conductivity of 1.38 W/m·K. The thermal conductivity of silicon oxide is one hundredth or less of the thermal conductivity of silicon, and STI using silicon oxide as a trench filler therefore prevents thermal diffusion.

A mixture Al₂O₃—SiO₂ is used in the above United States patent in order to reduce stress resulting from STI. However, it is estimated that this mixture has thermal conductance of at most 15 W/m·K to 20 W/m·K. STI therefore still prevents thermal diffusion.

Moreover, a mixed oxide Al₂O₃—SiO₂ or ZrO₂—SiO₂ has the same thermal expansion coefficient as that of silicon only when the mixed oxide has specific composition. Therefore, the composition of each mixed oxide must be precisely controlled in a production process when these mixed oxides are used as an STI filler. Inaccurate control of the composition may cause variation in characteristics of elements.

In view of the above problems, it is an object of the present invention to enable stress resulting from a trench isolation region formed in a semiconductor substrate or a semiconductor layer which is formed from silicon to be easily reduced and to enable improvement in heat release through the trench isolation region.

In a semiconductor device and a manufacturing method thereof according to the present invention, at least a part of a trench in a trench isolation region is filled with an insulating metal nitride, i.e., aluminum nitride, in order to achieve the above object.

More specifically, the present invention implements a highly reliable semiconductor device by using as a filler of a trench isolation region (STI) aluminum nitride (AlN) whose thermal expansion coefficient is close to that of silicon and whose thermal conductance is at least several times higher than that of Al₂O₃—SiO₂.

FIG. 1 shows temperature dependence of respective linear thermal expansion coefficients of aluminum nitride, silicon, and silicon oxide. FIG. 2 shows respective thermal conductance values of aluminum nitride, silicon oxide, silicon, and aluminum oxide. It can be seen from FIG. 2 that the thermal conductance of aluminum nitride is about 80 W/m·k, which is much higher than the thermal conductance of silicon oxide, 1.38 W/m·k. Aluminum nitride is therefore found effective for thermal diffusion.

More specifically, a semiconductor device according to a first aspect of the present invention includes a semiconductor layer of silicon and a trench isolation region. The semiconductor layer has a plurality of element formation regions. The trench isolation region isolates the plurality of element formation regions from each other. The trench isolation region is formed by filling a trench formed in an upper part of the semiconductor layer with an insulating metal nitride. A thermal expansion coefficient of the insulating metal nitride is closer to that of silicon than a thermal expansion coefficient of silicon oxide is to that of silicon.

According to the semiconductor device of the first aspect of the invention, stress resulting from trench isolation formed in the semiconductor layer of silicon can be easily reduced without precisely controlling the composition of the trench filler. Moreover, since the insulating metal nitride has higher thermal conductance than that of silicon oxide, heat release through the trench isolation region is improved. Such reduced stress and improved heat conduction of the trench isolation region improve reliability of the semiconductor device.

A semiconductor device according to a second aspect of the present invention includes a semiconductor layer of silicon and a trench isolation region. The semiconductor layer has a plurality of element formation regions. The trench isolation region isolates the plurality of element formation regions from each other. The trench isolation region is formed by filling a part of a trench formed in an upper part of the semiconductor layer with an insulating metal nitride. A thermal expansion coefficient of the insulating metal nitride is closer to that of silicon than a thermal expansion coefficient of silicon oxide is to that of silicon.

According to the semiconductor device of the second aspect of the invention, stress resulting from trench isolation formed in a semiconductor substrate of silicon or in the semiconductor layer of silicon can be easily reduced without precisely controlling the composition of the trench filler. Moreover, since the insulating metal nitride has higher thermal conductance than that of silicon oxide, heat release through the trench isolation region is improved. Such reduced stress and improved heat conduction of the trench isolation region improve reliability of the semiconductor device.

Note that, unlike the semiconductor device of the first aspect of the invention, only a part of the trench is filled with the insulating metal nitride in the semiconductor device of the second aspect of the invention. Therefore, reduction in stress and improvement in heat conduction in the trench isolation region are less than those in the semiconductor device of the first aspect of the invention. However, filling the remaining part of the trench with silicon oxide or the like facilitates planarization of the upper part of the trench isolation region because silicon oxide is softer than nitrides. Moreover, since silicon oxide is highly compatible with a semiconductor process, unexpected defects are less likely to be generated.

Accordingly, a remaining part of the trench is preferably filled with silicon oxide in the semiconductor device of the second aspect of the invention.

In the semiconductor device of the first or second aspect of the invention, the insulating metal nitride is preferably aluminum nitride.

Preferably, the semiconductor device of the first or second aspect of the invention further includes an adhesive layer of aluminum oxide which is formed between the trench and the insulating metal nitride in the trench isolation region. This structure can reduce interface defects between the bottom and the wall surface of the trench and the insulating metal nitride filling the trench.

Preferably, the semiconductor device of the first or second aspect of the invention further includes a surface protective film of aluminum oxide which is formed on the insulating metal nitride in the trench isolation region.

In the semiconductor device of the first aspect of the invention, the plurality of element formation regions are preferably divided into a first region in which stress from the trench isolation region to an element which is formed in each element formation region is reduced and a second region in which stress from the trench isolation region to an element which is formed in each element formation region is not reduced. Preferably, a trench in the first region is filled with the insulating metal nitride and a trench in the second region is filled with silicon oxide. In this structure, the trench in the second region is filled with silicon oxide and stress from the trench isolation region is not reduced in the second region. Therefore, in the second region, conventional circuit design resources can be used as well as characteristics of semiconductor elements can be improved by stress distortion caused by silicon oxide.

A method for manufacturing a semiconductor device according to a third aspect of the invention includes the steps of: (a) forming in an upper part of a semiconductor layer of silicon a plurality of trenches for separating a plurality of element formation regions from each other; (b) depositing an insulating film of aluminum nitride on the semiconductor layer so that the plurality of trenches are filled with the insulating film; and (c) forming a trench isolation region from the insulating film deposited in the plurality of trenches by removing the insulating film deposited outside the plurality of trenches by planarization.

In the method for manufacturing a semiconductor device according to the third aspect of the invention, the insulating film of aluminum nitride is deposited in the plurality of trenches which separate the plurality of element formation regions from each other. Therefore, stress resulting from trench isolation formed in the semiconductor layer of silicon can be easily reduced without precisely controlling the composition of the trench filler. Moreover, since aluminum nitride has higher thermal conductance than that of silicon oxide, heat release through the trench isolation region is improved. Such reduced stress and improved heat conduction of the trench isolation region improve reliability of the semiconductor device.

Preferably, the method for manufacturing a semiconductor device according to the third aspect of the invention further includes the steps of (d) forming on the semiconductor layer a protective film for protecting the semiconductor layer before the step (a), and (e) removing the protective film from the semiconductor layer after the step (c).

Preferably, the method for manufacturing a semiconductor device according to the third aspect of the invention further includes the step of (f) forming an insulating oxide film on a bottom and a wall surface of each of the plurality of trenches between the step (a) and the step (b).

Preferably, the method for manufacturing a semiconductor device according to the third aspect of the invention further includes the step of (g) forming an adhesive layer of aluminum oxide on a bottom and a wall surface of each of the plurality of trenches between the step (a) and the step (b).

Preferably, the method for manufacturing a semiconductor device according to the third aspect of the invention further includes the step of (h) oxidizing a surface of the insulating film in each of the plurality of trenches after the step (c).

A method for manufacturing a semiconductor device according to a fourth aspect of the invention includes the steps of: (a) forming in an upper part of a semiconductor layer of silicon a plurality of trenches for separating a plurality of element formation regions from each other; (b) depositing a first insulating film of aluminum nitride on the semiconductor layer so that a part of each of the plurality of trenches is filled with the first insulating film; (c) depositing a second insulating film of silicon oxide on the first insulating film so that a remaining part of each of the plurality of trenches is filled with the second insulating film; and (d) forming a trench isolation region from the first and second insulating films deposited in the plurality of trenches by removing the first and second insulating films deposited outside the plurality of trenches by planarization.

In the method for manufacturing a semiconductor device according to the fourth aspect of the invention, the first insulating film of aluminum nitride is deposited on the semiconductor layer of silicon so that a part of each of the plurality of trenches is filled with the first insulating film. The second insulating film of silicon oxide is then deposited on the first insulating film so that the remaining part of each of the plurality of trenches is filled with the second insulating film. The first and second insulating films are then planarized so that the first and second insulating films deposited outside the plurality of trenches are removed. A semiconductor device of the fourth aspect of the invention can thus be reliably obtained.

A method for manufacturing a semiconductor device according to a fifth aspect of the invention includes the steps of: (a) dividing a main surface of a semiconductor layer of silicon which has a plurality of element formation regions into a first region in which stress from an isolation region to an element to be formed in each element formation region is reduced and a second region in which stress from the isolation region to an element to be formed in each element formation region is not reduced; (b) forming in an upper part of the semiconductor layer including the first and second regions a plurality of trenches for separating the plurality of element formation regions from each other; (c) depositing a first insulating film of aluminum nitride on the semiconductor layer so that each trench in the first region is filled with the first insulating film; (d) depositing a second insulating film of silicon oxide on the semiconductor layer so that each trench in the second region is filled with the second insulating film; (e) forming a first trench isolation region from the first insulating film deposited in each trench of the first region by removing the first insulating film deposited outside each trench of the first region by planarization; and (f) forming a second trench isolation region from the second insulating film deposited in each trench of the second region by removing the second insulating film deposited outside each trench of the second region by planarization.

In the method for manufacturing a semiconductor device according to the fifth aspect of the invention, the first insulating film of aluminum nitride is deposited in each trench in the first region of the semiconductor layer of silicon, and the second insulating film of silicon oxide is deposited in each trench in the second region of the semiconductor layer. A semiconductor device of the fifth aspect of the invention can thus be reliably obtained.

In the method for manufacturing a semiconductor device according to the fifth aspect of the invention, the step (d) preferably includes after the step (b) the steps of (g) depositing the second insulating film on the semiconductor layer so that the plurality of trenches in the first and second regions are filled with the second insulating film, and (h) removing the second insulating film in the first region. The step (c) is preferably conducted after the step (h).

In the method for manufacturing a semiconductor device according to the fifth aspect of the invention, the first insulating film and the second insulating film are preferably planarized by polishing. A polishing temperature of the first insulating film is preferably higher than a polishing temperature of the second insulating film.

### BRIEF DESCRIPTION OF THE DRAWINGS

FIG. 1 is a graph showing temperature dependence of respective linear thermal expansion coefficients of aluminum nitride, silicon, and silicon oxide;

FIG. 2 is a graph showing respective thermal conductance values of aluminum nitride, silicon oxide, silicon, and aluminum oxide;

FIG. 3 is a cross-sectional view of an isolation region (STI) which is used in a semiconductor device of a first embodiment of the present invention;

FIGS. 4A, 4B and 4C are cross-sectional views sequentially showing a method for manufacturing an isolation region (STI) which is used in a semiconductor device of the first embodiment of the present invention;

FIGS. 5A, 5B and 5C are cross-sectional views sequentially showing a method for manufacturing an isolation region (STI) which is used in a semiconductor device of the first embodiment of the present invention;

FIGS. 6A and 6B are cross-sectional views sequentially showing a method for manufacturing a semiconductor device of the first embodiment of the present invention;

FIG. 7 is a graph showing respective Vickers hardness values of silicon oxide, aluminum nitride, silicon aluminum oxynitride, and the like;

FIG. 8 is a graph showing the ratios of respective CMP (Chemical Mechanical Polishing) rates of aluminum nitride and silicon nitride to the CMP rate of silicon oxide (it is herein assumed that the CMP rate of silicon oxide is 1);

FIG. 9 is a cross-sectional view of an isolation region (STI) which is used in a semiconductor device of a second embodiment of the present invention;

FIGS. 10A and 10B are cross-sectional views sequentially showing a method for manufacturing an isolation region (STI) which is used in a semiconductor device of the second embodiment of the present invention;

FIG. 11 is a cross-sectional view of an isolation region (STI) which is used in a semiconductor device of a third embodiment of the present invention;

FIGS. 12A and 12B are cross-sectional views sequentially showing a method for manufacturing an isolation region (STI) which is used in a semiconductor device of the third embodiment of the present invention;

FIG. 13 is a cross-sectional view of an isolation region (STI) which is used in a semiconductor device of a fourth embodiment of the present invention;

FIG. 14 is a cross-sectional view of an isolation region (STI) which is used in a semiconductor device of a modification of the fourth embodiment of the present invention;

FIG. 15 is a cross-sectional view of an isolation region (STI) which is used in a semiconductor device of a fifth embodiment of the present invention; and

FIGS. 16A and 16B are cross-sectional views sequentially showing a method for manufacturing an isolation region (STI) which is used in a semiconductor device of the fifth embodiment of the present invention.

### DETAILED DESCRIPTION OF THE INVENTION

### First Embodiment

Hereinafter, a semiconductor device and a manufacturing method thereof according to a first embodiment of the present invention will be described with reference to the drawings.

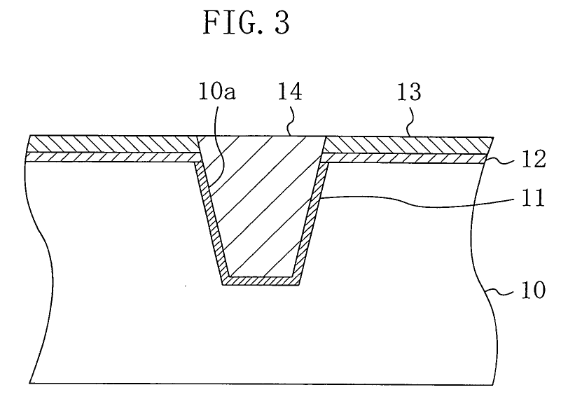

FIG. 3 shows a cross-sectional structure of a trench isolation region (STI) in the semiconductor device of the first embodiment.

As shown in FIG. 3, a semiconductor substrate 10 of silicon (Si) has a groove (trench) 10a which is 0.25 μm to 0.30 μm deep and 0.20 μm or less wide on top. For example, the trench 10a is filled with aluminum nitride, an insulating metal nitride. An STI 14 of aluminum nitride is thus formed in the upper part of the semiconductor substrate 10. Note that the above dimensions of the trench 10a are shown by way of example only and the dimensions of the trench 10a are not limited to the above values. The semiconductor substrate 10 is not limited to a silicon wafer. The semiconductor substrate 10 may be an SOI (silicon on insulator) substrate having an insulating layer formed at a prescribed depth from a surface.

A sidewall oxide film 11 of silicon oxide (SiO₂) is formed at the interface between the STI 14 and the semiconductor substrate 10 in order to reduce the interface state of the trench 10a. The sidewall oxide film 11 is formed by, e.g., thermal oxidation and has a thickness of about 15 nm. A protective oxide film 12 of silicon oxide and a protective nitride film 13 of silicon nitride (Si₃O₄) are formed in order to protect the surface of the semiconductor substrate 10 during formation of the STI 14. The protective oxide film 12 is about 10 nm thick. The protective nitride film 13 is about 100 nm thick and is formed on the protective oxide film 12.

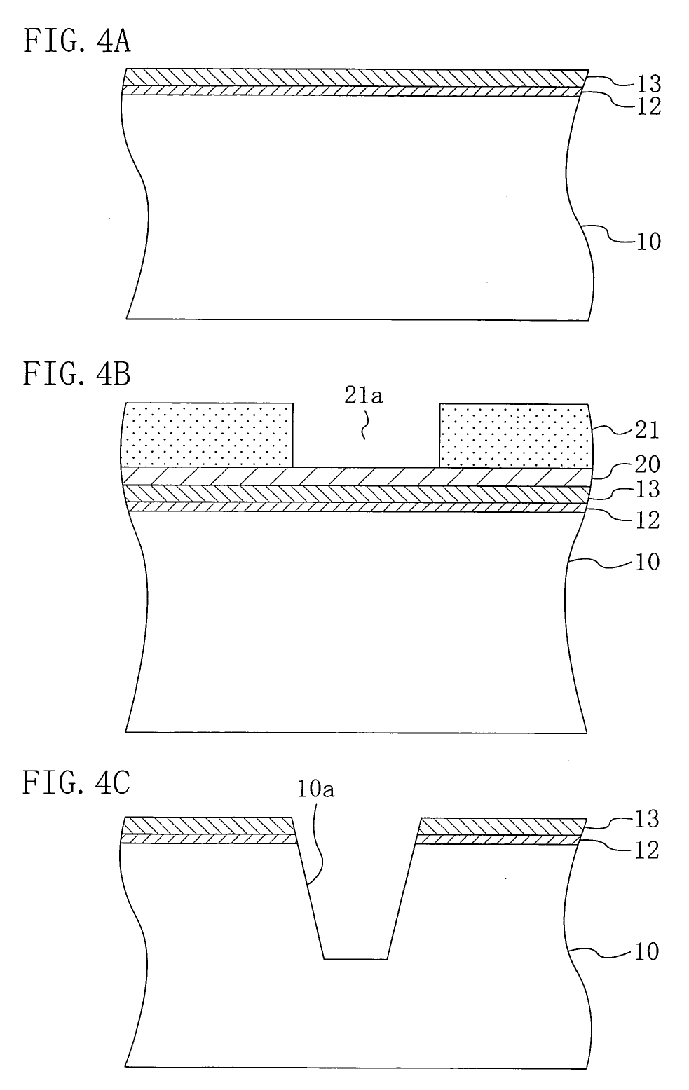

Hereinafter, a method for manufacturing this STI structure will be described with reference to FIGS. 4A to 4C, FIGS. 5A to 5C, and FIGS. 6A and 6B.

As shown in FIG. 4A, a protective oxide film 12 is formed by oxidizing the surface of the semiconductor substrate 10 by a thermal oxidation method. A protective nitride film 13 is then deposited on the protective oxide film 12 by a low-pressure chemical vapor deposition (LP-CVD) method.

As shown in FIG. 4B, an anti-reflection film 20 of an organic resin material is then applied to the semiconductor substrate 10 by a spinner, and a resist pattern 21 having an opening 21a in an STI formation region is formed on the anti-reflection film 20 by a lithography method.

As shown in FIG. 4C, by using the resist pattern 21 as a mask, the protective nitride film 13, the protective oxide film 12, and the semiconductor substrate 10 are sequentially etched to form a trench 10a in the upper part of the semiconductor substrate 10. When dry etching is used to form the trench 10a, etching gas consisting mainly of, e.g., fluorocarbon is used for the protective oxide film 12 and the protective nitride film 13 and etching gas consisting mainly of, e.g., chlorine or hydrogen bromide is used for the semiconductor substrate 10. The resist pattern 21 is then removed by ashing or the like.

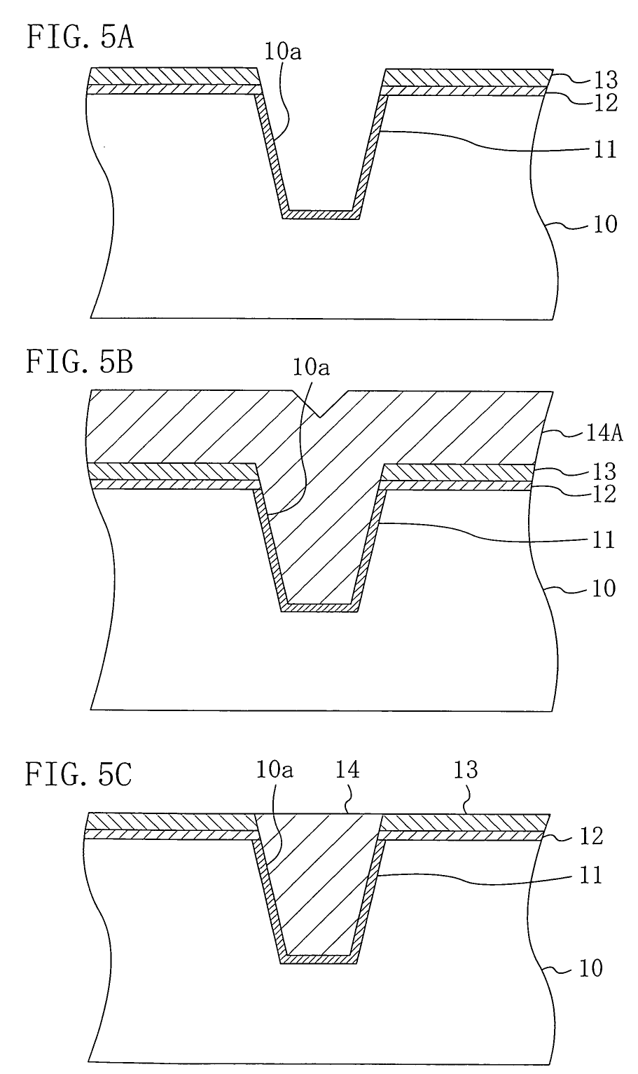

As shown in FIG. 5A, a sidewall oxide film 11 is then formed on the bottom and the wall surface of the trench 10a by heating the semiconductor substrate 10 in an oxidizing atmosphere.

As shown in FIG. 5B, an insulating nitride film 14A of aluminum nitride (AlN) is then deposited on the protective nitride film 13 by, e.g., a high-density plasma chemical vapor deposition (HDP-CVD) method so that the trench 10a is filled with the insulating nitride film 14A. This deposition process is conducted under the following conditions: substrate temperature: 200° C. to 400° C.; ratio of a flow rate of a nitriding gas material to a flow rate of an organic metal aluminum gas material: 2 to 10; chamber pressure: about 200 Pa to about 2,000 Pa; and RF (radio frequency) power: about 4,000 W. Ammonia (NH₃) can be mainly used as a nitriding gas material. Trimethylaluminum (TMA) or triethylaluminum (TEA) or the like can be used as an organic metal aluminum gas material. Hydrogen (H₂) can be mainly used as carrier gas for carrying each gas material to a chamber. When a thermal chemical vapor deposition (thermal CVD) method is used instead of the HDP-CVD method, the substrate is heated to about 600° C. to about 800° C.

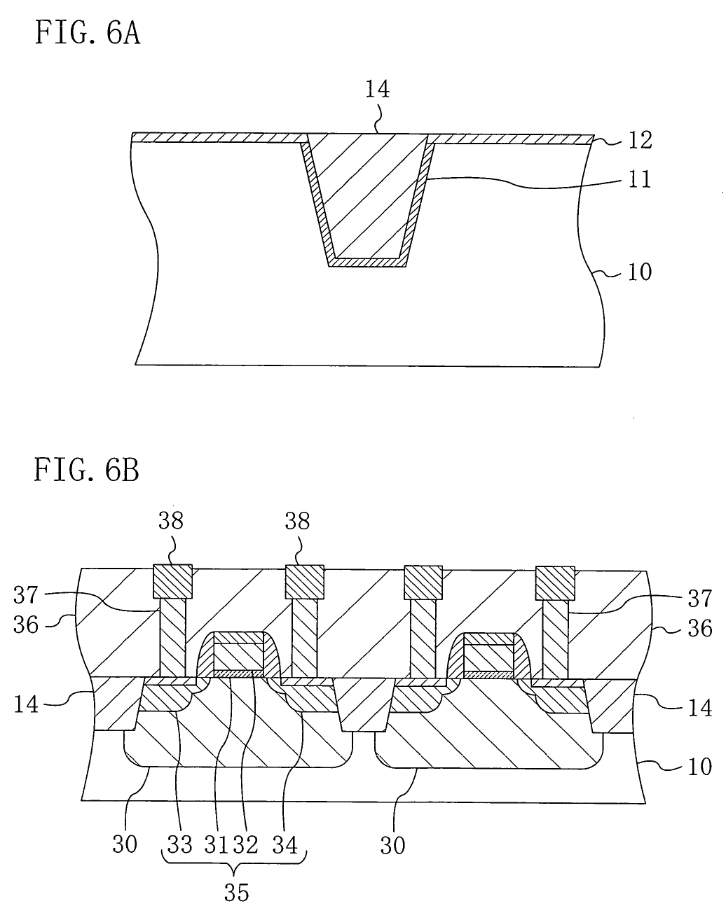

As shown in FIG. 5C, an STI 14 is then formed from the insulating nitride film 14A by planarizing the insulating nitride film 14A by a chemical mechanical polishing (CMP) method until the protective nitride film 13 is exposed. As shown in FIG. 6A, the protective nitride film 13 is then removed by using an etchant consisting mainly of phosphoric acid.

As shown in FIG. 6B, the protective oxide film 12 is then removed from the semiconductor substrate 10 by hydrofluoric acid (HF) or the like, and MIS (metal insulator semiconductor) transistors 35 are respectively formed in element formation regions of the semiconductor substrate 10 which are separated from each other by a plurality of STIs 14.

A method for forming MIS transistors will now be described briefly. As is known in the art, a p-type well 30 is first formed in each element formation region, and a gate insulating film 31 and a gate electrode 32 are selectively formed on the p-type well 30. Source/drain diffusion layers 33, 34 are then formed on both sides of the gate electrode 32 in the p-type well 30 by an ion implantation method. Thereafter, an interlayer insulating film 36 is formed on the semiconductor substrate 10 so as to cover each MIS transistor 35. The interlayer insulating film 36 is then planarized and contact plugs 37 connected to the source/drain diffusion layers 33, 34 of the MIS transistors 35 are formed in the planarized interlayer insulating film 36. Wirings 38 electrically connected to the respective contact plugs 37 are then formed in the upper part of the interlayer insulating film 36.

Hereinafter, a method for polishing the insulating nitride film 14A to form the STI 14 will be described in detail.

The CMP polishing rate highly depends on mechanical hardness of a material to be polished. The difference in hardness between aluminum nitride and silicon oxide or between aluminum nitride and silicon nitride is therefore important in the CMP method for polishing the insulating nitride film 14A as shown in FIG. 5C. In order that the protective nitride film 13 serves as a CMP stop film in the process of mechanically and chemically polishing the insulating nitride film 14A, the insulating nitride film 14A, a filler of the trench 10a, needs to be softer than the protective nitride film 13.

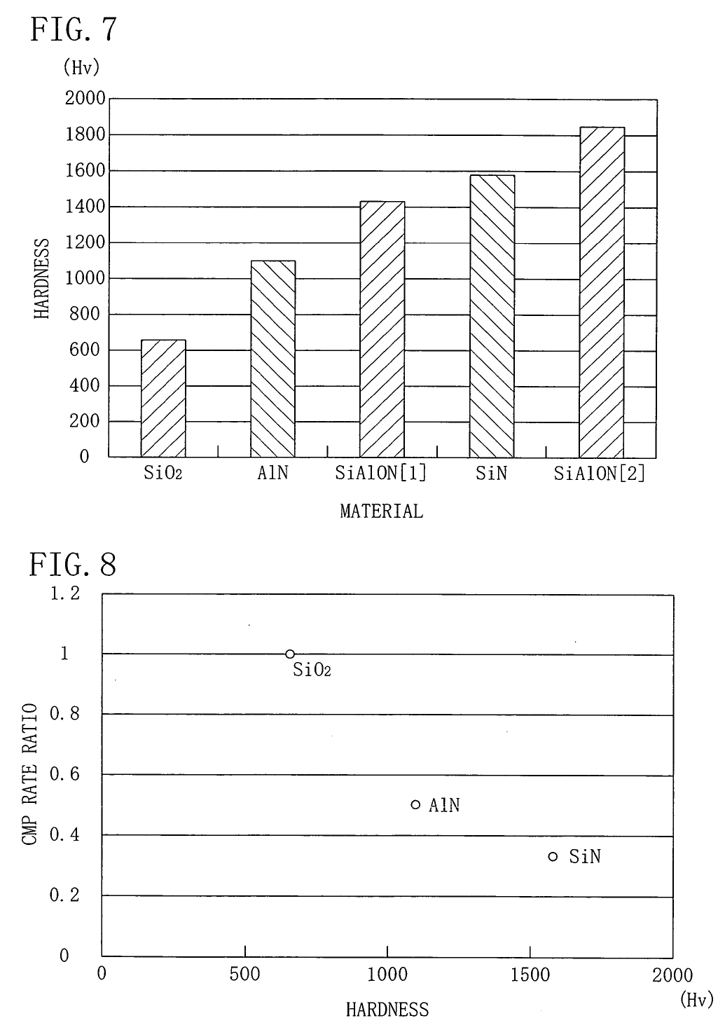

FIG. 7 shows respective Vickers hardness values Hv of silicon oxide (SiO₂), aluminum nitride (AlN), silicon aluminum oxynitride (SiAlON[1]), silicon nitride (SiN), and silicon aluminum oxynitride (SiAlON[2]). It can be seen from FIG. 7 that AlN is softer than SiN and that the same CMP process as that for silicon oxide, a conventional filler of the trench 10a, can be used for AlN. In FIG. 7, the respective composition ratios of Al and O in SiAlON[2] are larger than those of Al and O in SiAlON[1].

FIG. 8 shows the relation between the CMP rate and Vickers hardness Hv. In FIG. 8, it is assumed that the CMP rate for silicon oxide is 1. It can be seen from FIG. 8 that the protective nitride film 13 functions as a CMP stop film.

As a pretreatment of the CMP process, a surface natural oxide film (aluminum oxide) formed at the surface of the insulating nitride film 14A is removed by a chemical solution containing hydrofluoric acid. Aluminum oxide is very hard and therefore can serve as an etch stop layer in the CMP process. However, aluminum oxide degrades CMP selectivity, that is, the ratio of the polishing rate of the insulating nitride film 14A of aluminum nitride to the polishing rate of the protective nitride film 13 of silicon nitride.

In the CMP process of FIG. 5C, the insulating nitride film 14A is polished by using neutral silica-based slurry. This polishing is conducted under the following conditions: pressure: about 6.9×10³ Pa; head rotational speed: about 85 rpm; table rotational speed: about 90 rpm; and slurry flow rate: about 200 ml/min.

Before the protective nitride film 13 is removed, the STI 14 is selectively etched with respect to the protective nitride film 13 by using a neutral or alkaline etchant of about 85° C. in order to adjust the height of the top surface of the STI 14 from the main surface of the semiconductor substrate 10. Aluminum nitride (AlN) which forms the STI 14 easily reacts with a water-containing etchant at high temperature, producing aluminum hydroxide having soluble hydroxyl groups (AlN+3H₂O=Al(OH)₃+NH₃). The STI 14 is thus selectively etched with respect to the protective nitride film 13. The protective nitride film 13 is then etched by a phosphoric-acid-based etchant.

According to the first embodiment, aluminum nitride (AlN), an insulating metal nitride, is used as a filler for the trench 10a of the STI 14. Therefore, stress resulting from the STI 14 in the semiconductor substrate 10 of silicon (Si) can be easily reduced without precisely controlling the composition of a compound which is used as a filler of the trench 10a. Moreover, aluminum nitride has larger thermal conductance than that of silicon oxide (SiO₂) and therefore heat release through the STI 14 is improved. Such reduced stress resulting from the STI 14 and improved heat conduction through the STI 14 can significantly improve operation reliability of the MIS transistors 35.

### Second Embodiment

Hereinafter, a semiconductor device and a manufacturing method thereof according to a second embodiment of the present invention will be described with reference to the drawings.

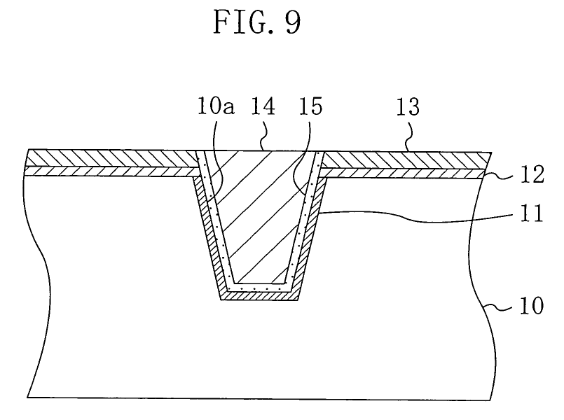

FIG. 9 shows a cross-sectional structure of a trench isolation region (STI) in the semiconductor device of the second embodiment. In FIG. 9, the same elements as those of FIG. 3 are denoted with the same reference numerals and characters, and description thereof will be omitted.

As shown in FIG. 9, an adhesive layer 15 of aluminum oxide (Al₂O₃) is formed between an STI 14 of aluminum nitride (AlN) and a sidewall oxide film 11 which is formed on the bottom and the wall surface of a trench 10a formed in the upper part of a semiconductor substrate 10. The adhesive layer 15 is about 5 nm thick and is formed in order to improve adhesion between the sidewall oxide film 11 and the STI 14.

The adhesive layer 15 is formed not only on the inner surface of the trench 10a but on the respective end surfaces of a protective oxide film 12 and a protective nitride film 13 which are located on the trench 10a side. This structure can prevent interface defects between the protective oxide film 12 and the STI 14 from acting as charge traps. In the second embodiment, interface defects between the protective oxide film 12 and the STI 14 can be reduced by forming around the STI 14 the adhesive layer 15 of aluminum oxide having stable material properties (physical properties).

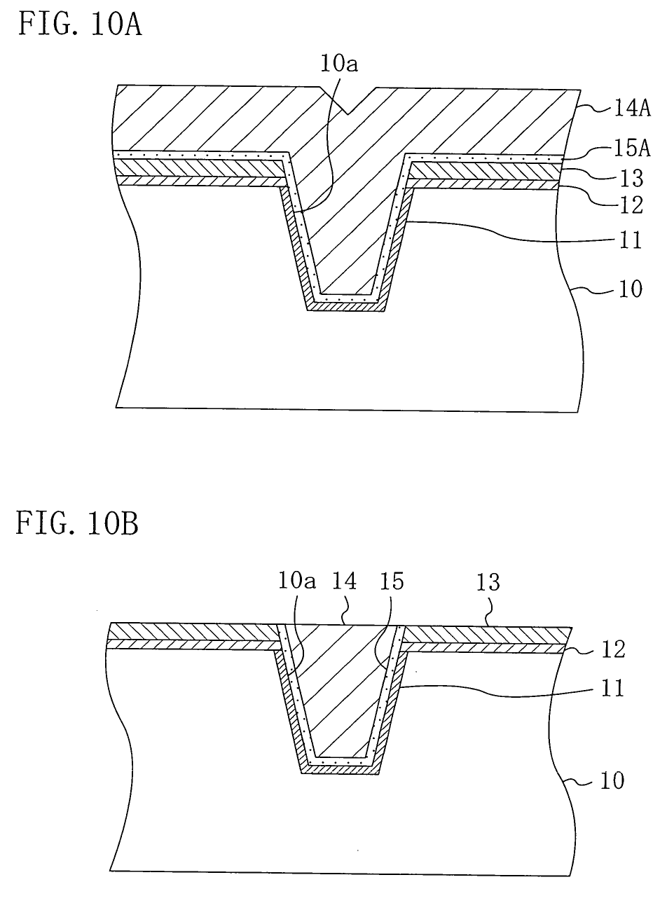

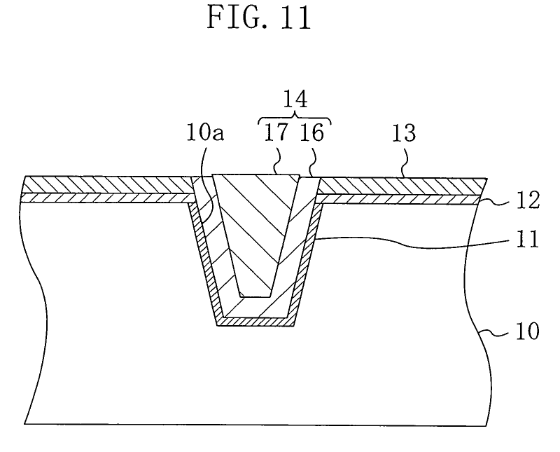

A method for manufacturing this STI structure will be described with reference to FIGS. 10A and 10B. Only a method for forming the adhesive layer 15 will be described below. The manufacturing method of the STI structure of the second embodiment is otherwise the same as that of the first embodiment.

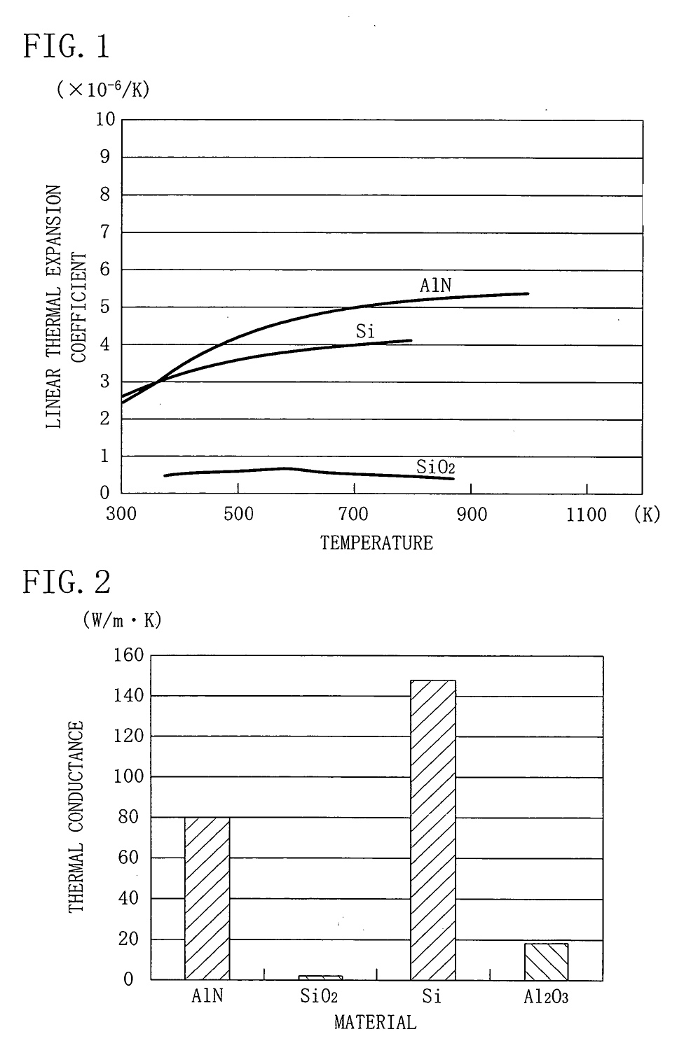

As shown in FIG. 1A, a protective oxide film 12 and a protective nitride film 13 are sequentially formed on a main surface of a semiconductor substrate 10. A trench 10a is then selectively formed in the upper part of the semiconductor substrate 10. A sidewall oxide film 11 is formed on the inner surface of the trench 10a.

By, e.g., a thermal CVD method, an adhesive-layer formation layer 15A of aluminum oxide is deposited on the whole surface of the protective nitride film 13 and the trench 10a. In the deposition process, the substrate temperature is about 300° C. to about 600° C., TMA or TEA is used as an organic metal aluminum material, and oxygen (O₂) or ozone (O₃) is used as an oxidizing agent. An atomic layer deposition (ALD) method may be used instead of the thermal CVD method. As a post-treatment of the deposition process, annealing is conducted for about 60 seconds in an oxygen atmosphere of about 600° C. to about 800° C. This enables formation of an adhesive-layer formation layer 15A of better quality aluminum oxide. As in the first embodiment, an insulating nitride film 14A of aluminum nitride (AlN) is then deposited on the adhesive-layer formation layer 15A by, e.g., an HDP-CVD method so that the trench 10a is filled with the insulating nitride film 14A.

As shown in FIG. 10B, the insulating nitride film 14A deposited on the adhesive-layer formation layer 15A is then planarized by a CMP method until the protective nitride film 13 is exposed. An STI 14 is thus formed from the insulating nitride film 14A.

According to the second embodiment, the adhesive-layer formation layer 15A of aluminum oxide as well as the protective nitride film 13 function as an etch stop layer. Therefore, higher selectivity can be obtained for the insulating nitride film 14A. Note that the adhesive-layer formation layer 15A which remains after the CMP process can be removed by hydrofluoric acid.

### Third Embodiment

Hereinafter, a semiconductor device and a manufacturing method thereof according to a third embodiment of the present invention will be described with reference to the drawings.

FIG. 11 shows a cross-sectional structure of a trench isolation region (STI) in the semiconductor device of the third embodiment. In FIG. 11, the same elements as those of FIG. 3 are denoted with the same reference numerals and characters, and description thereof is omitted.

As shown in FIG. 11, an STI 14 of the third embodiment has a first filler 16 of aluminum nitride (AlN) and a second filler 17 of silicon oxide (SiO₂) as fillers of a trench 10a. The first filler 16 is formed on the bottom and the wall surface of the trench 10a. The remaining portion of the trench 10a is filled with the second filler 17.

In the third embodiment, the trench 10a formed in the upper part of the semiconductor substrate 10 is not filled only with the first filler 16 of aluminum nitride but with both the first filler 16 and the second filler 17. More specifically, the trench 10a is partially filled with the first filler 16 so that the trench 10a still has a recessed portion. The recessed portion of the trench 10a is then filled with the second filler 17 of silicon oxide. Since oxide silicon (the first filler 16) is softer than aluminum nitride (the second filler 17), the polishing rate is increased in the CMP process of the first filler 16 and the second filler 17. Moreover, silicon oxide has better deposition coverage than that of aluminum nitride and is more consistent with and more compatible with a process using a semiconductor substrate 10 of silicon.

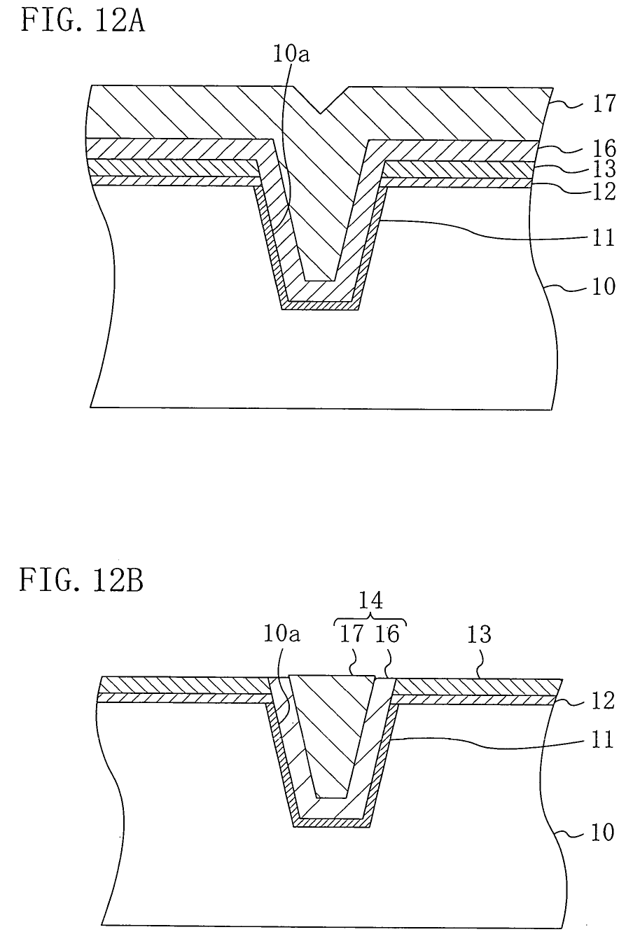

Hereinafter, a method for manufacturing this STI structure will be described with reference to FIGS. 12A and 12B. Only a method for depositing the first filler 16 and the second filler 17 and a method for polishing the deposited film will be described below. The manufacturing method of the STI structure of the third embodiment is otherwise the same as that of the first embodiment.

As shown in FIG. 12A, a protective oxide film 12 and a protective nitride film 13 are sequentially formed on a main surface of a semiconductor substrate 10. A trench 10a is then selectively formed in the upper part of the semiconductor substrate 10. A sidewall oxide film 11 is then formed in the inner surface of the trench 10a.

A first filler 16 of aluminum nitride is then deposited on the protective nitride film 13 and on the bottom and the wall surface of the trench 10a by, e.g., an HDP-CVD method. The trench 10a is thus partially filled with the first filler 16 so that the trench 10a still has a recessed portion. The thickness of the first filler 16 is at most one half of an opening width of the trench 1a. A second filler 17 of silicon oxide is then deposited on the first filler 16 by an HDP-CVD method so that the recessed portion of the trench 10a is filled with the second filler 17.

As shown in FIG. 12B, the first filler 16 and the second filler 17 are then planarized by a CMP method until the protective nitride film 13 is exposed. An STI 14 is thus formed from the first filler 16 and the second filler 17. In the third embodiment, a reduced amount of aluminum nitride is deposited as the first filler 16, and silicon oxide which is softer than aluminum nitride is deposited on aluminum nitride (the first filler 16) as the second filler 17. This improves the CMP rate and throughput of the CMP process. Note that the first filler 16 deposited outside the trench 10a may be removed by a method other than a CMP method. For example, the first filler 16 deposited outside the trench 10a may be removed by the following method: the second filler 17 deposited outside the trench 10a is first removed by a CMP method. By using the remaining second filler 17 (the second filler 17 in the trench 10a) as a mask, the first filler 16 deposited outside the trench 10a is then removed by dry etching using, for example, mixed gas of chlorine (Cl₂) and argon (Ar) or mixed gas of methane (CH₄), hydrogen (H₂) and argon (Ar).

According to the third embodiment, both silicon oxide and aluminum nitride are used as a filler of the STI 14. Therefore, the STI 14 has a reduced proportion of aluminum nitride. The use of silicon oxide reduces the effect of reducing stress resulting from the STI 14 but improves consistency with a conventional semiconductor process. As a result, generation of defects can be suppressed, enabling manufacturing of highly reliable devices.

### Fourth Embodiment

Hereinafter, a semiconductor device and a manufacturing method thereof according to a fourth embodiment of the present invention will be described with reference to the drawings.

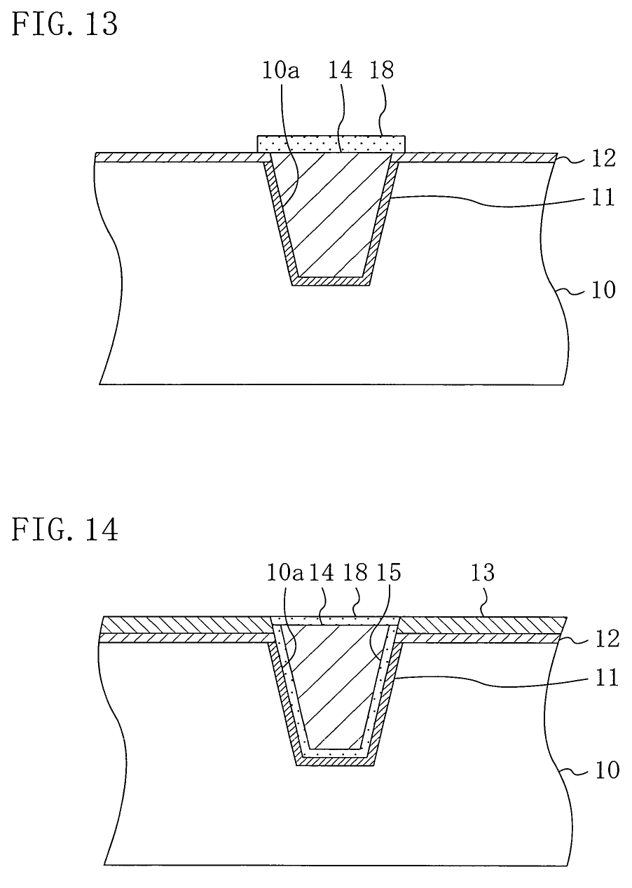

FIG. 13 shows a cross-sectional structure of a trench isolation region (STI) in the semiconductor device of the fourth embodiment. In FIG. 13, the same elements as those of FIG. 3 are denoted with the same reference numerals and characters, and description thereof will be omitted.

As shown in FIG. 13, an STI 14 of the fourth embodiment has a surface protective film 18 of aluminum oxide (Al₂O₃). The surface protective film 18 covers the top surface of the STI 14. For example, the surface protective film 18 is about 5 nm to about 20 nm thick.

Aluminum nitride (AlN) is water soluble at high temperature and therefore is less consistent with a conventional semiconductor process. Accordingly, aluminum oxide is advantageous in terms of material properties but is hard to use.

In the fourth embodiment, aluminum oxide which is chemically extremely stable is used as a surface protective film 18, and the surface protective film 18 of aluminum oxide is formed on the surface of the STI 14 of aluminum nitride. The reaction between water and aluminum nitride can therefore be prevented even in a high-temperature water vapor atmosphere. Therefore, compatibility with a conventional semiconductor process can be improved.

For example, the surface protective film 18 of aluminum oxide can be formed on the top surface of the STI 14 of aluminum nitride by the following method: after the step of FIG. 6A of the first embodiment, annealing is conducted in an oxidizing atmosphere at about 600° C. to about 800° C. for about 60 seconds. For example, the oxidizing atmosphere is an atmosphere containing oxygen, oxygen plasma, or ozone.

### Modification of Fourth Embodiment

Hereinafter, a semiconductor device according to a modification of the fourth embodiment of the present invention will be described with reference to the drawings.

FIG. 14 shows a cross-sectional structure of a trench isolation region (STI) in a semiconductor device according to a modification of the fourth embodiment. In FIG. 14, the same elements as those of FIG. 3 are denoted with the same reference numerals and characters, and description thereof will be omitted.

As shown in FIG. 14, an STI 14 of this modification has a surface protective film 18 which covers the top surface of the STI 14. In addition, the STI 14 of this modification has an adhesive layer 15 of aluminum oxide which is formed on the bottom and the wall surface of a trench 10a as in the second embodiment.

As described before, the adhesive layer 15 improves adhesion between the STI 14 of aluminum nitride and the sidewall oxide film 11 and reduces interface defects between the STI 14 and the protective oxide film 12. Moreover, since the top surface of the STI 14 is covered with the stable surface protective film 18, aluminum nitride of the STI 14 does not react with high temperature water vapor. Therefore, compatibility with a conventional semiconductor process is improved.

Note that the adhesive layer 15 and the surface protective film 18 can be formed by the methods described in the second and fourth embodiments.

### Fifth Embodiment

Hereinafter, a semiconductor device and a manufacturing method thereof according to a fifth embodiment of the present invention will be described with reference to the drawings.

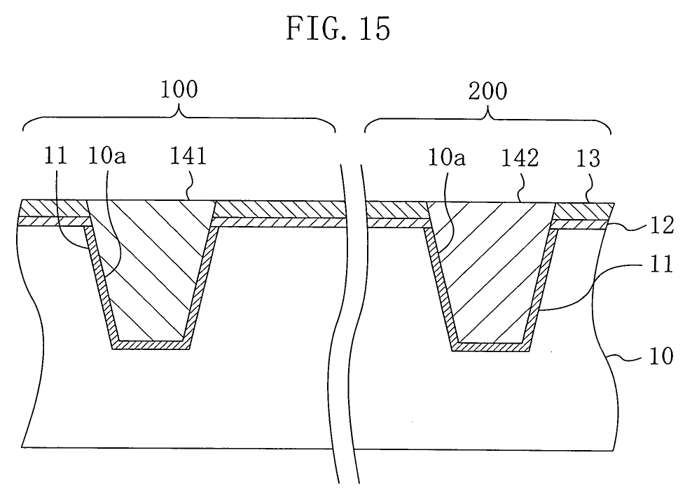

FIG. 15 shows a cross-sectional structure of a trench isolation region (STI) in the semiconductor device of the fifth embodiment. In FIG. 15, the same elements as those of FIG. 3 are denoted with the same reference numerals and characters, and description thereof will be omitted.

In the fifth embodiment, a main surface of a semiconductor substrate 10 is divided into a first circuit region 100 and a second circuit region 200. A first STI 141 having a conventional STI structure is formed in the first circuit region 100 and a second STI 142 of the present invention is formed in the second circuit region 200. The first STI 141 is formed by filling a trench 10a with silicon oxide, and the second STI 142 is formed by filling a trench 10a with aluminum nitride.

As described above, the first STI 141 having a conventional STI structure is formed in the first circuit region 100. For example, an input/output (IO) section which needs to prevent a leakage current of semiconductor elements can therefore be formed in the first circuit region 100. On the other hand, the second STI 142 of the present invention having excellent heat release capability is formed in the second circuit region 200. For example, a logic section having transistors whose temperature rises significantly during operation can therefore be formed in the second circuit region 200.

From another point of view, the first STI 141 which causes relatively large stress is formed in the first circuit region 100. Therefore, semiconductor elements whose characteristics can be improved by stress distortion of element formation regions caused by the first STI 141 can be formed in the first circuit region 100. On the other hand, the second STI 142 which causes small stress is formed in the second circuit region 200. Therefore, circuitry formed from elements whose characteristics can be improved without requiring such stress distortion can be formed in the second circuit region 200.

The fifth embodiment thus provides the following effects:

A dielectric constant ε of aluminum oxide is 9 and a dielectric constant ε of silicon oxide is 3.9. Aluminum oxide thus has a larger dielectric constant ε than that of silicon oxide. Therefore, if MIS transistors are formed in the second circuit region 200, the substrate capacity between the gate and the STI may be increased. Moreover, since stress from the second STI 142 to element formation regions are reduced, STI stress dependence of MIS transistors is different from that of MIS transistors in a conventional example. Therefore, when aluminum nitride is used as an STI filler, transistors must be designed to have different characteristics parameters from those of transistors in a conventional structure in which silicon oxide is used as an STI filler.

In the fifth embodiment, however, the circuit formation region of the semiconductor substrate 10 is divided into the first circuit region 100 in which the first STI 141 having a conventional STI structure is formed and the second circuit region 200 in which the second STI 142 having the STI structure of the present invention is formed. As a result, conventional circuit design resources can be used in the first circuit region 100, whereas semiconductor circuitry can be formed by using transistors adapted to reduced stress in the second circuit region 200.

For reliability of circuitry in the second circuit region 200 as well, the present embodiment is important in order to maintain consistency with circuitry in the first circuit region 100, i.e., circuitry having conventional design resources.

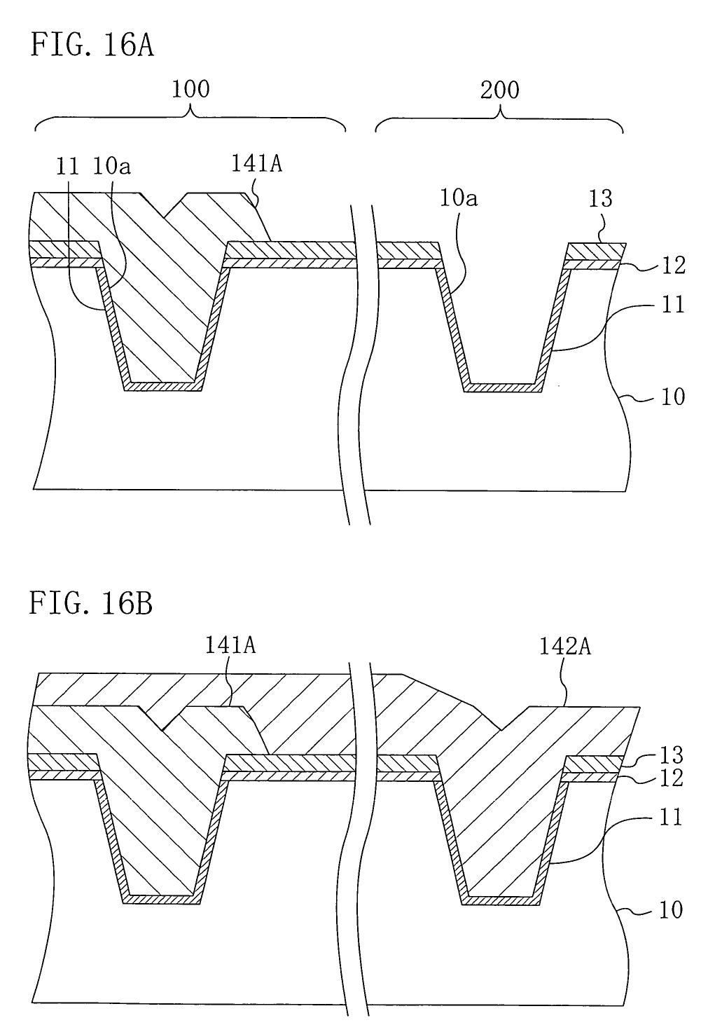

Hereinafter, a method for manufacturing the above STI structure will be described with reference to FIGS. 16A and 16B.

As shown in FIG. 16A, a protective oxide film 12 and a protective nitride film 13 are sequentially formed in a first circuit region 100 and a second circuit region 200 on a main surface of a semiconductor substrate 10. A plurality of trenches 10a are then selectively formed in the upper part of the semiconductor substrate 10. A sidewall oxide film 11 is then formed on the inner surface of each trench 10a. An insulating oxide film 141A of silicon oxide (SiO₂) is then deposited on the protective nitride film 13 by, e.g., a HDP-CVD method so that each trench 10a is filled with the insulating oxide film 141A. The insulating oxide film 141A of the second circuit region 200 is selectively removed by a hydrofluoric acid solution so that the protective nitride film 13 and the trench 10a in the second circuit region 200 are exposed. Since the sidewall oxide film 11 is formed from silicon oxide, the sidewall oxide film 11 in the trench 10a of the second circuit region 200 is removed simultaneously by this process. Therefore, a sidewall oxide film 11 is formed again on the side surface and the bottom of the exposed trench 10a by a thermal oxidation method.

As shown in FIG. 16B, an insulating nitride film 142A of aluminum nitride (AlN) is then deposited on the whole main surface of the semiconductor substrate 10 including the insulating oxide film 141A by, e.g., an HDP-CVD method so that the exposed trench 10a in the second circuit region 200 is filled with the insulating nitride film 142A.

The insulating nitride film 142A is then selectively removed by a CMP method. Aluminum nitride (the insulating nitride film 142A) can be polished at high selectivity with respect to silicon oxide when the CMP method is conducted at about 85° C. The insulating oxide film 141A of silicon oxide is then polished. As a result, a first STI 141 and a second STI 142 can be formed as shown in FIG. 15.

The following effects can be obtained when aluminum nitride is polished at high temperature to form the second STI 142: aluminum nitride (AlN) is soluble in an (organic) alkaline solution, and activation energy is about 15 kcal/mol (according to “Appl. Phys. Lett. 67, 21 Aug. 1995, pp. 1119-1121”). On the other hand, silicon oxide (SiO₂) is not soluble in an (organic) alkaline solution. Therefore, by raising the polishing temperature, aluminum nitride can be polished at higher selectivity. Provided that the insulating nitride film 142A having about the same thickness as the depth of the trench 10a, for example, having a thickness of 250 nm, is to be polished in several minutes, a desirable polishing temperature is 85° C. or higher at which a chemical etching rate of 40 nm/min is obtained. Note that the desirable polishing temperature depends also on a kind of polishing slurry and its concentration and material properties of aluminum nitride. In this case, the upper limit of the polishing temperature is about 95° C. In other words, the upper limit of the polishing temperature is such a temperature that water contained in slurry does not boil.

The above polishing temperature conditions for aluminum nitride are the same in other embodiments. By using the above polishing temperature conditions, selectivity of aluminum nitride with respect to silicon oxide can be improved. In the fifth embodiment, it is necessary to improve CMP selectivity of aluminum nitride with respect to silicon oxide which is softer than aluminum nitride. Such high temperature CMP is therefore more preferable in the fifth embodiment.

In the fifth embodiment, the insulating oxide film 141A for forming the first STI 141 and the insulating nitride film 142A for forming the second STI 142 are deposited on both the first circuit region 100 and the second circuit region 200. Alternatively, however, the insulating oxide film 141A may be selectively deposited only on the first circuit region 100 and the insulating nitride film 142A may be selectively deposited only on the second circuit region 200.

As has been described above, the semiconductor device and the manufacturing method thereof according to the present invention can reduce stress from the STI structure to semiconductor elements and improve heat release capability of the STI structure. As a result, reliability of semiconductor devices can be improved. Therefore, the present invention is useful for a semiconductor device having a trench isolation region for isolating a plurality of elements from each other, a method for manufacturing such a semiconductor device, and the like.

What is claimed is:

1. A semiconductor device, comprising:
a semiconductor layer of silicon which has a plurality of element formation regions; and
a trench isolation region for isolating the plurality of element formation regions from each other, the trench isolation region being formed by filling a trench formed in an upper part of the semiconductor layer with an insulating metal nitride, and a thermal expansion coefficient of the insulating metal nitride being closer to that of silicon than a thermal expansion coefficient of silicon oxide is to that of silicon.

2. The semiconductor device according to claim 1, wherein the insulating metal nitride is aluminum nitride.

3. The semiconductor device according to claim 1, further comprising an adhesive layer of aluminum oxide which is formed between the trench and the insulating metal nitride in the trench isolation region.

4. The semiconductor device according to claim 1, further comprising a surface protective film of aluminum oxide which is formed on the insulating metal nitride in the trench isolation region.

5. The semiconductor device according to claim 1, wherein
the plurality of element formation regions are divided into a first region in which stress from the trench isolation region to an element which is formed in each element formation region is reduced and a second region in which stress from the trench isolation region to an element which is formed in each element formation region is not reduced, and
a trench in the first region is filled with the insulating metal nitride and a trench in the second region is filled with silicon oxide.

6. A semiconductor device, comprising:
a semiconductor layer of silicon which has a plurality of element formation regions; and
a trench isolation region for isolating the plurality of element formation regions from each other, the trench isolation region being formed by filling a part of a trench formed in an upper part of the semiconductor layer with an insulating metal nitride, and a thermal expansion coefficient of the insulating metal nitride being closer to that of silicon than a thermal expansion coefficient of silicon oxide is to that of silicon.

7. The semiconductor device according to claim 6, wherein a remaining part of the trench is filled with silicon oxide.

8. The semiconductor device according to claim 6, wherein the insulating metal nitride is aluminum nitride.

9. The semiconductor device according to claim 6, further comprising an adhesive layer of aluminum oxide which is formed between the trench and the insulating metal nitride in the trench isolation region.

10. The semiconductor device according to claim 8, further comprising a surface protective film of aluminum oxide which is formed on the insulating metal nitride in the trench isolation region.

11. The semiconductor device according to claim 8, wherein
the plurality of element formation regions are divided into a first region in which stress from the trench isolation region to an element which is formed in each element formation region is reduced and a second region in which stress from the trench isolation region to an element which is formed in each element formation region is not reduced, and
a trench in the first region is filled with the insulating metal nitride and a trench in the second region is filled with silicon oxide.

12. A method for manufacturing a semiconductor device, comprising the steps of:
(a) forming in an upper part of a semiconductor layer of silicon a plurality of trenches for separating a plurality of element formation regions from each other;
(b) depositing an insulating film of aluminum nitride on the semiconductor layer so that the plurality of trenches are filled with the insulating film; and
(c) forming a trench isolation region from the insulating film deposited in the plurality of trenches by removing the insulating film deposited outside the plurality of trenches by planarization.

13. The method according to claim 12, further comprising the steps of:
(d) forming on the semiconductor layer a protective film for protecting the semiconductor layer before the step (a); and
(e) removing the protective film from the semiconductor layer after the step (c).

14. The method according to claim 12, further comprising the step of (f) forming an insulating oxide film on a bottom and a wall surface of each of the plurality of trenches between the step (a) and the step (b).

15. The method according to claim 12, further comprising the step of (g) forming an adhesive layer of aluminum oxide on a bottom and a wall surface of each of the plurality of trenches between the step (a) and the step (b).

16. The method according to claim 12, further comprising the step of (h) oxidizing a surface of the insulating film in each of the plurality of trenches after the step (c).

17. A method for manufacturing a semiconductor device, comprising the steps of:
(a) forming in an upper part of a semiconductor layer of silicon a plurality of trenches for separating a plurality of element formation regions from each other;
(b) depositing a first insulating film of aluminum nitride on the semiconductor layer so that a part of each of the plurality of trenches is filled with the first insulating film;
(c) depositing a second insulating film of silicon oxide on the first insulating film so that a remaining part of each of the plurality of trenches is filled with the second insulating film; and
(d) forming a trench isolation region from the first and second insulating films deposited in the plurality of trenches by removing the first and second insulating films deposited outside the plurality of trenches by planarization.

18. A method for manufacturing a semiconductor device, comprising the steps of:
(a) dividing a main surface of a semiconductor layer of silicon which has a plurality of element formation regions into a first region in which stress from an isolation region to an element to be formed in each element formation region is reduced and a second region in which stress from the isolation region to an element to be formed in each element formation region is not reduced;
(b) forming in an upper part of the semiconductor layer including the first and second regions a plurality of trenches for separating the plurality of element formation regions from each other;
(c) depositing a first insulating film of aluminum nitride on the semiconductor layer so that each trench in the first region is filled with the first insulating film;
(d) depositing a second insulating film of silicon oxide on the semiconductor layer so that each trench in the second region is filled with the second insulating film;
(e) forming a first trench isolation region from the first insulating film deposited in each trench in the first region by removing the first insulating film deposited outside each trench of the first region by planarization; and
(f) forming a second trench isolation region from the second insulating film deposited in each trench in the second region by removing the second insulating film deposited outside each trench of the second region by planarization.

19. The method according to claim 18, wherein the step (d) includes after the step (b) the steps of (g) depositing the second insulating film on the semiconductor layer so that the plurality of trenches in the first and second regions are filled with the second insulating film, and (h) removing the second insulating film in the first region, and the step (c) is conducted after the step (h).

20. The method according to claim 18, wherein the first insulating film and the second insulating film are planarized by polishing, and a polishing temperature of the first insulating film is higher than a polishing temperature of the second insulating film.
